(19) United States
(12) Patent Application Publication
(10) Pub. No.: US 2004/0169544 A1
(43) Pub. Date: Sep. 2, 2004

(54) Flip-flop design with built-in voltage translation

(76) Inventors: Aninda K. Roy, San Jose, CA (US); Claude R. Gauthier, Cupertino, CA (US)

Correspondence Address: OSHA & MAY L.L.P./SUN, 1221 MCKINNEY, SUITE 2800, HOUSTON, TX, 77010, US

(21) Appl. No.: 10/376,790

(22) Filed: Feb. 28, 2003

(51) Int. Cl. H03K 17/16

(52) U.S. Cl. 327/379

(57) ABSTRACT

A flip-flop with built-in voltage translation is used in a transmission system so as to combine core flip-flop circuitry with a input/output voltage translator. The flip-flop with built-in voltage translation dynamically latches data and translates a core power supply voltage swing at an input of the flip-flop to an input/output power supply voltage swing at an output of the flip-flop. Thus, the flip-flop, dependent on a clock input, is able to output a data signal having a translated voltage swing.

### BACKGROUND OF INVENTION

As shown in FIG. 1, a typical computer system 10 has, among other components, a microprocessor 12, one or more forms of memory 14, integrated circuits 16 having specific functionalities, and peripheral computer resources (not shown), e.g., monitor, keyboard, software programs, etc. These components communicate with one another via communication paths 18, e.g., wires, buses, etc., to accomplish the various tasks of the computer system 10.

When an integrated circuit (16 in FIG. 1) communicates with another integrated circuit, i.e., “chip-to-chip communication,” data is transmitted in a series of binary 0's and 1's from a transmitting circuit to a receiving circuit.

FIG. 2 shows a portion of a typical chip-to-chip communication, or input/output transmission, system 20. Particularly, FIG. 2 shows a portion of a core 22 of a transmitting circuit and a communication sub-system 24 that is arranged to prepare, or ready, a data signal from the core 22 for input/output transmission.

The core 22 includes a flip-flop 26 that inputs data 28 and is clocked by a clock input signal, CLK 30. As shown in FIG. 2, the flip-flop 26 operates off of a power supply voltage of V_{DD}_{_{—}}_{CORE}. The communication sub-system 24 includes a voltage translator 32, a pre-driver 34, and a driver 36. Because the communication sub-system operates off a power supply voltage of V_{DD}_{_{—}}_{IO}, the voltage translator 32 is used to translate the voltage swing of a data signal 38 from the core 22 to a voltage swing of the communication sub-system 24. Once a voltage swing of the data signal 38 is translated, the data signal outputted from the voltage translator 32 (now having a voltage swing different than that of the voltage swing the data signal had when it was outputted from the core 22) is fed to a pre-driver 34, which, in turn, outputs the data signal to a stronger driver 36 that drives the data signal to an input/output data channel 40.

FIG. 3 shows a circuit diagram of a typical voltage translator 32. The data signal 42 (from the core 22 in FIG. 2), which has a voltage swing of the core (22 in FIG. 2) serves as an input to a transmission gate 44 and an inverter 46. When the transmission gate 44 is ‘on,’ the data signal 42 is allowed to pass and serves as an input to transistor 48. If the data signal 42 is ‘high,’ transistor 48 switches ‘on’ and inverter 46 outputs ‘low’ to an input to transistor 50, which, in turn, switches transistor 50 ‘off.’ Due to transistor 48 being ‘on,’ a ‘low’ is propagated through transistor 48 to an input to transistor 52, which, in turn, switches transistor 52 ‘on.’ Due to transistor 52 being ‘on,’ an output 54 of the voltage translator 32 is driven ‘high’ by a connection to V_{DD}_{_{—}}_{IO} through the ‘on’ transistor 52. Thus, when the data signal 42 (having a voltage swing of V_{DD}_{_{—}}_{CORE}) is ‘high,’ the voltage translator 32 outputs ‘high’ with a voltage swing of V_{DD}_{_{—}}_{IO}. Moreover, because the output 54 of the voltage translator 32 is ‘high,’ transistor 56, which has an input connected to the output 54 of the voltage translator 32, is ensured to be ‘off,’ thereby cutting of a substantial amount of leakage current flow from V_{DD}_{_{—}}_{IO} to the input to transistor 52.

If the data signal 42 is ‘low’ when the transmission gate 44 is ‘on,’ transistor 48 switches ‘off’ and inverter 46 outputs ‘high’ to the input to transistor 50, which, in turn, switches transistor 50 ‘on.’ Due to transistor 50 being ‘on,’ a ‘low’ is propagated through transistor 50 to the output 54 of the voltage translator 32. Thus, when the data signal 42 (having a voltage swing of V_{DD}_{_{—}}_{CORE}) is ‘low,’ the voltage translator 32 outputs ‘low’ with a voltage swing of V_{DD}_{_{—}}_{IO}. Moreover, because the output 54 of the voltage translator 32 is ‘low,’ transistor 56, which has an input connected to the output 54 of the voltage translator 32, is ensured to be ‘on,’ which, in turn, causes the input to transistor 52 to get connected to V_{DD}_{_{—}}_{IO} through the ‘on’ transistor 56. This, in effect, ensures that transistor 52 is ‘off,’ thereby cutting of a substantial amount of leakage current flow from V_{DD}_{_{—}}_{IO} to the output 54 of the voltage translator 32.

As shown in FIG. 2, the voltage translation 32 (described in detail with reference to FIG. 3) typically occurs after the last flip-flop 26 in the transmitting path. Thus, the voltage translator 32 often adds jitter to the overall transmission path. Such jitter leads to delay variability in the transmission of data from the core 22 to the input/output data channel (40 in FIG. 2), which, in turn, may cause timing problems in data transmission.

### SUMMARY OF INVENTION

According to one aspect of the present invention, a transmission system comprises: a flip-flop arranged to dynamically store data dependent on an input data signal and a clock signal, where the input data signal has a voltage swing dependent on a first power supply voltage, and where the flip-flop is arranged to generate, dependent on the input data signal and the clock signal, an output data signal having a voltage swing dependent on a second power supply voltage; and driver circuitry arranged to receive and transmit the output data signal.

According to another aspect, an integrated circuit comprises flip-flop circuitry having: circuitry arranged to receive an input data signal having a voltage swing dependent on a first power supply voltage; circuitry arranged to dynamically store data dependent on the input data signal and a clock signal; and circuitry arranged to establish at least one voltage value on at least one node dependent on at least one of the input data signal and the clock signal, where the at least one voltage value is subsequently used to latch a value for an output data signal of the flip-flop circuitry, where the output data signal has a voltage swing dependent on a second power supply voltage, and where the first power supply voltage and the second power supply voltage are not equal.

According to another aspect, a method for transmitting a data signal comprises inputting a clock signal, inputting an input data signal having a voltage swing dependent on a first power supply voltage, and dynamically latching a value for the data signal dependent on the clock signal and the input data signal, where the data signal has a voltage swing dependent on a second power supply voltage

According to another aspect, a circuit module comprises means for inputting a clock signal, means for inputting an input signal having a voltage swing dependent on a first power supply voltage, means for dynamically storing data dependent on the clock signal and the input signal, and means for generating an output signal dependent on the means for dynamically storing, where the output signal is arranged to have a voltage swing dependent on a second power supply voltage, and where the first power supply voltage and the second power supply voltage are not equal.

Other aspects and advantages of the invention will be apparent from the following description and the appended claims.

### BRIEF DESCRIPTION OF DRAWINGS

FIG. 1 shows a typical computer system.

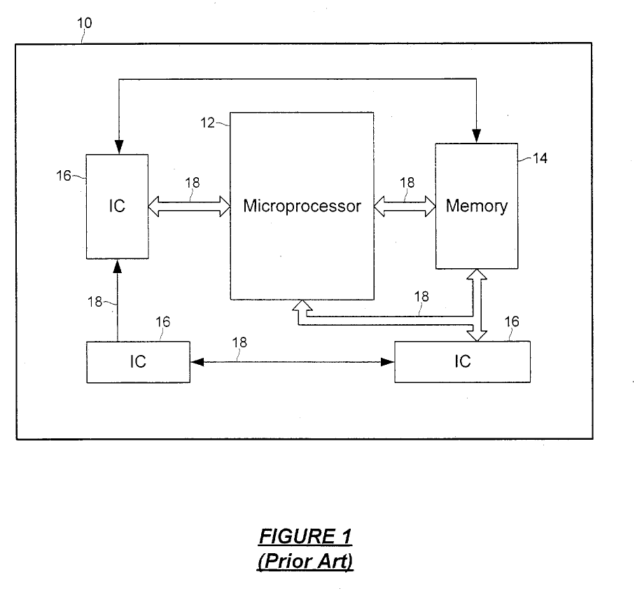

FIG. 2 shows a block diagram of a portion of a circuit-to-circuit transmission system.

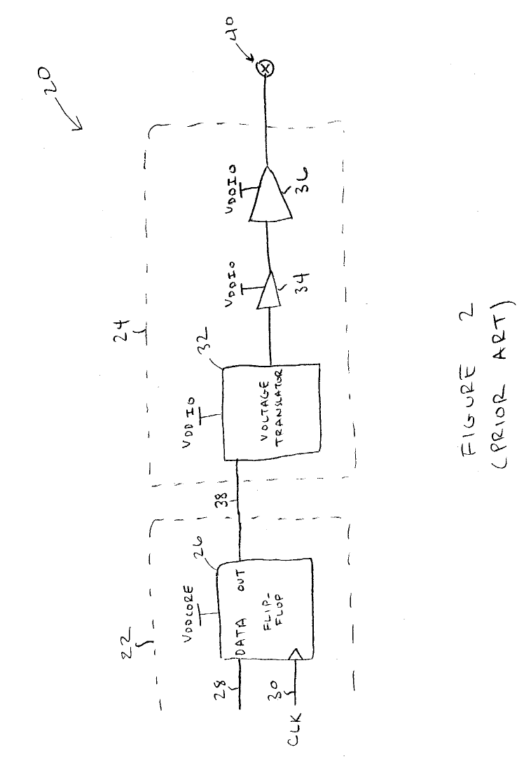

FIG. 3 shows a circuit diagram of a typical voltage translator.

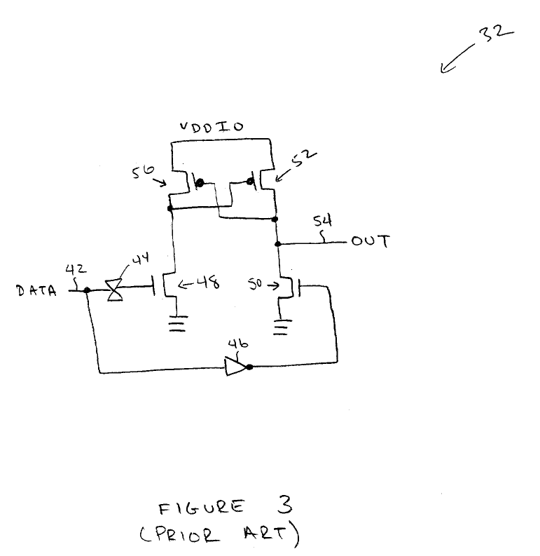

FIG. 4 shows a block diagram of a portion of a transmission system in accordance with an embodiment of the present invention.

FIG. 5 shows a circuit diagram of a combined flip-flop and voltage translator in accordance with an embodiment of the present invention.

### DETAILED DESCRIPTION

To reduce delay variability present introduced by a voltage translator positioned after a flip-flop in a transmission path, embodiments of the present invention relate to a flip-flop design having built-in voltage translation capability.

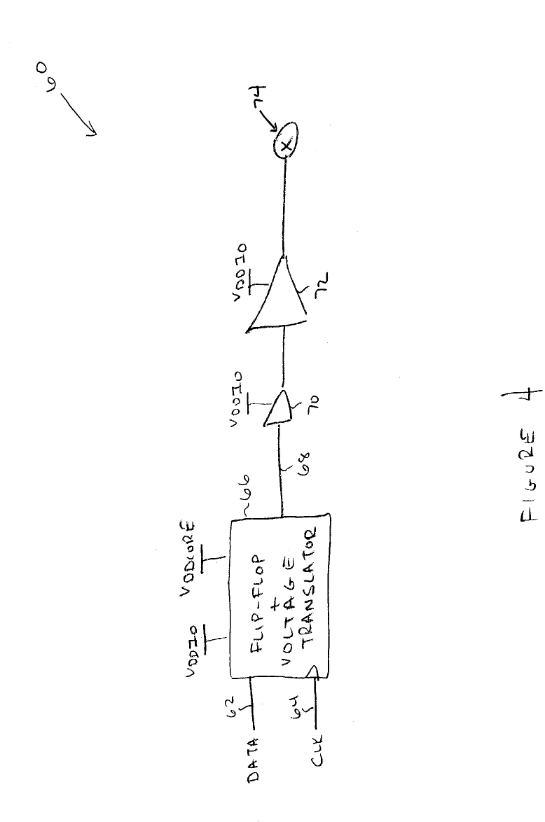

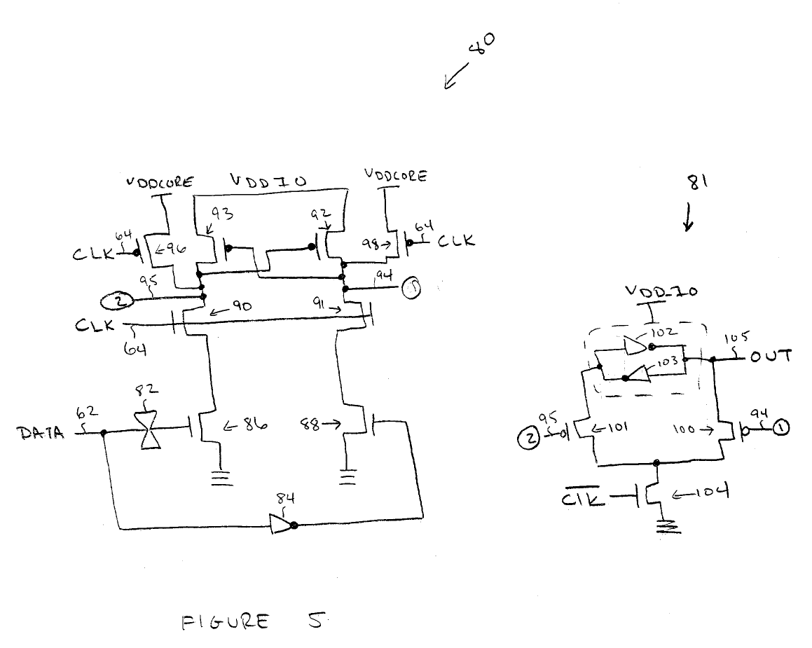

FIG. 4 shows a portion of an exemplary transmission system 60 in accordance with an embodiment of the present invention. In FIG. 4, a data signal 62 and a clock signal 64 serve as inputs to a combined flip-flop and voltage translator stage (also referred to as “flip-flop with built-in voltage translation” and “flip-flop with built-in voltage translator”) 66. The combined flip-flop and voltage translator stage 66 is connected to both a power supply voltage of V_{DD}_{_{—}}_{CORE} and a power supply voltage of V_{DD}_{_{—}}_{IO}. A detailed description of the combined flip-flop and voltage translator stage 66 is given below with reference to FIG. 5. The combined flip-flop and voltage translator stage 66 outputs a data signal 68 having a voltage swing of V_{DD}_{_{—}}_{IO} to a pre-driver 70, which, in turn, feeds the data signal to a stronger driver 72, which, in turn, drives the data signal onto an input/output data channel 74.

FIG. 5 shows a circuit diagram of an exemplary combined flip-flop and voltage translator stage in accordance with an embodiment of the present invention. As illustrated in FIG. 5, the combined flip-flop and voltage translator stage includes a master stage 80 and a slave stage 81. When the clock signal, CLK 64 (also shown in FIG. 4), is ‘low,’ transistors 96 and 98, which both have inputs operatively connected to the clock signal 64, allow a voltage of V_{DD}_{_{—}}_{CORE} to propagate through them to nodes 1 94 and 2 95, respectively. Nodes 1 94 and 2 95 serve as inputs to transistors 100 and 101 in the slave stage 81. Because nodes 1 94 and 2 95 are ‘high,’ transistors 100 and 101 remain or switch ‘off,’ thereby allowing a latch formed by inverters 102 and 103 to continue outputting the value the latch was outputting before the clock signal 64 went ‘low.’

When the clock signal 64 goes ‘high,’transistors 96 and 98 switch ‘off’ and transistors 90 and 91, which both have inputs connected to the clock signal 64, switch ‘on.’ If a transmission gate 82 is ‘on’ and the data signal 62 (also shown in FIG. 4) is ‘high,’ the ‘high’ is fed to an input to transistor 86, which, in turn, allows a ‘low’ to propagate through the ‘on’ transistor 86 to a terminal of the ‘on’ transistor 90, which, in turn, propagates the ‘low’ through the ‘on’ transistor 90 to node 2 95 and an input to transistor 92. The ‘low’ at the input to transistor 92 causes transistor 92 to switch ‘on,’ which, in turn, causes node 1 94 to be driven ‘high’ due to it getting connected to V_{DD}_{_{—}}_{IO} through the ‘on’ transistor 92. Thus, when the data signal 62 goes ‘high’ and the clock signal 64 is ‘high,’ node 1 94, after some propagation delay, goes ‘high’ and node 2 95, after some propagation delay, goes ‘low.’ Moreover, because node 1 94 is ‘high,’ transistor 93, which has an input connected to node 1 94, is ensured to be ‘off,’ thereby cutting of a substantial amount of leakage current flow from V_{DD}_{_{—}}_{IO} through the ‘on’ transistor 93 to node 2 95.

In the slave stage 81, the ‘low’ on node 2 95 switches transistor 100 ‘on.’ However, because the clock signal 64 is ‘high,’ a transistor 104, which has an input connected to the complement of the clock signal 64, remains ‘off,’ thereby cutting off transistor 100. However, as soon as the clock signal 64 goes ‘low,’ transistor 104 switches ‘on’ and a ‘low’ is propagated through the ‘on’ transistors 104 and 101 to the latch formed by inverters 102 and 103, which, in turn, causes the slave stage 81 to output ‘high’ on an output 105 of the combined flip-flop and voltage translator stage. After some propagation delay, nodes 1 94 and 2 95 are reset to V_{DD}_{_{—}}_{CORE} as described above. Note that although transistors 100 and 101 are switched ‘off’ when nodes 1 94 and 2 95 are reset to ‘high,’ the combined flip-flop and voltage translator stage continues to output ‘high’ on output 105 due to the latching (using inverters 102 and 103) of the ‘high’ as soon as the clock signal 64 went ‘low.’

As discussed above, when the clock signal 64 goes back ‘high,’ transistors 96 and 98 switch ‘off’ and transistors 90 and 91, which both have inputs connected to the clock signal 64, switch ‘on.’ If the transmission gate 82 is ‘on’ and the data signal 62 (also shown in FIG. 4) is ‘low,’ the ‘low’ is fed to an inverter 84, which, in turn, outputs ‘high’ to an input to transistor 88, which, in turn, allows a ‘low’ to propagate through the ‘on’ transistor 88 to a terminal of the ‘on’ transistor 91, which, in turn, propagates the ‘low’ through the ‘on’ transistor 91 to node 1 94 and an input to transistor 93. The ‘low’ at the input to transistor 93 causes transistor 93 to switch ‘on,’ which, in turn, causes node 2 95 to be driven ‘high’ due to it getting connected to V_{DD}_{_{—}}_{IO} through the ‘on’ transistor 93. Thus, when the data signal 62 goes ‘low’ and the clock signal 64 is ‘high,’ node 1 94, after some propagation delay, goes ‘low’ and node 2 95, after some propagation delay, goes ‘high.’ Moreover, because node 2 95 is ‘high,’ transistor 92, which has an input connected to node 2 95, is ensured to be ‘off,’ thereby cutting of a substantial amount of leakage current flow from V_{DD}_{_{—}}_{IO} to node 1 94.

In the slave stage 81, the ‘low’ on node 1 94 switches transistor 101 ‘on.’ However, because the clock signal 64 is ‘high,’ transistor 104, which has an input connected to the complement of the clock signal 64, remains ‘off,’ thereby cutting off transistor 101. However, as soon as the clock signal 64 goes ‘low,’ transistor 104 switches ‘on’ and a ‘low’ is propagated through the ‘on’ transistors 104 and 100 to the latch formed by inverters 102 and 103, which, in turn, causes the slave stage 81 to output ‘low’ on the output 105 of the combined flip-flop and voltage translator stage. After some propagation delay, nodes 1 94 and 2 95 are reset to V_{DD}_{_{—}}_{CORE} as described above. Note that although transistors 100 and 101 are switched ‘off’ when nodes 1 94 and 2 95 are reset to ‘high,’ the combined flip-flop and voltage translator stage continues to output ‘low’ on output 105 due to the latching (using inverters 102 and 103) of the ‘high’ as soon as the clock signal 64 went ‘low.’

As discussed in the description of FIG. 5, the combined flip-flop and voltage translator stage is capable of storing data and translating a voltage swing of a signal at an input of the combined flip-flop and voltage translator stage to a different voltage swing of a signal at an output of the combined flip-flop and voltage translator stage. Thus, those skilled in the art will appreciate that such a design is beneficial in transmission system design in that the design results in the reduction of jitter introduced after a last flip-flop in a transmission path.

Advantages of the present invention may include one or more of the following. In one or more embodiments, because a flip-flop and voltage translator are combined in circuitry along a transmission path, delay variability associated with a stand-alone voltage translator may be reduced.

In one or more embodiments, because a flip-flop and voltage translator are combined in circuitry along a transmission path, jitter along an input/output transmission may be reduced.

In one or more embodiments, because a flip-flop and voltage translator are combined in circuitry along a transmission path, signal timing from a designer's perspective may become less difficult than in designs that use a stand-alone voltage translator positioned after the last flip-flop in a transmitting data path.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

what is claimed is:

1. A transmission system, comprising:
a flip-flop arranged to dynamically store data dependent on an input data signal and a clock signal, wherein the input data signal has a voltage swing dependent on a first power supply voltage, and wherein the flip-flop is arranged to generate, dependent on the input data signal and the clock signal, an output data signal having a voltage swing dependent on a second power supply voltage; and
driver circuitry arranged to receive and transmit the output data signal.

2. The transmission system of claim 1, wherein the clock signal has a voltage swing dependent on the first power supply voltage.

3. The transmission system of claim 1, wherein the first power supply voltage and the second power supply voltage are not equal.

4. The transmission system of claim 1, wherein the first power supply voltage is a core power supply voltage.

5. The transmission system of claim 1, wherein the second power supply is an input/output transmission interface power supply voltage.

6. The transmission system of claim 1, the flip-flop comprising:
a master stage; and
a slave stage, wherein the master stage is operatively connected to the slave stage at a first node and second node,
wherein the master stage is arranged to control voltages on the first node and the second node dependent on the input data signal and the clock signal.

7. The transmission system of claim 6, wherein the slave stage is arranged to latch a value for the output data signal when the clock signal goes to a voltage that initially allows the slave stage to latch the value dependent on at least one of the first node and the second node.

8. The transmission system of claim 7, wherein the master stage is arranged to, after some propagation delay, reset the first node and the second node when the clock signal goes to the voltage.

9. The transmission system of claim 8, wherein the slave stage is arranged to continue to output the value after the master stage has reset the first node and the second node.

10. An integrated circuit, comprising:
flip-flop circuitry comprising:
circuitry arranged to receive an input data signal having a voltage swing dependent on a first power supply voltage,
circuitry arranged to dynamically store data dependent on the input data signal and a clock signal, and
circuitry arranged to establish at least one voltage value on at least one node dependent on at least one of the input data signal and the clock signal, wherein the at least one voltage value is subsequently used to latch a value for an output data signal of the flip-flop circuitry, wherein the output data signal has a voltage swing dependent on a second power supply voltage, and wherein the first power supply voltage and the second power supply voltage are not equal.

11. The integrated circuit of claim 10, wherein the first power supply voltage is a core power supply voltage.

12. The integrated circuit of claim 10, wherein the second power supply is an input/output transmission interface power supply voltage.

13. The integrated circuit of claim 10, wherein the clock signal has a voltage swing dependent on the first power supply voltage.

14. A method for transmitting a data signal, comprising:
inputting a clock signal;
inputting an input data signal having a voltage swing dependent on a first power supply voltage; and
dynamically latching a value for the data signal dependent on the clock signal and the input data signal, wherein the data signal has a voltage swing dependent on a second power supply voltage.

15. The method of claim 14, wherein the clock signal has a voltage swing dependent on the first power supply voltage.

16. The method of claim 14, wherein the first power supply voltage and the second power supply voltage are not equal.

17. The method of claim 14, wherein the first power supply voltage is a core power supply voltage.

18. The method of claim 14, wherein the second power supply is an input/output transmission interface power supply voltage.

19. A circuit module, comprising:
means for inputting a clock signal;
means for inputting an input signal having a voltage swing dependent on a first power supply voltage;
means for dynamically storing data dependent on the clock signal and the input signal; and
means for generating an output signal dependent on the means for dynamically storing, wherein the output signal is arranged to have a voltage swing dependent on a second power supply voltage,
wherein the first power supply voltage and the second power supply voltage are not equal.

20. The circuit module of claim 19, wherein the first power supply voltage is a core power supply voltage, and the second power supply voltage is an input/output transmission system power supply voltage.
